(19) United States
(12) Patent Application Publication
(10) Pub. No.: US 2024/0242007 A1
(43) Pub. Date: Jul. 18, 2024

(54) METHOD AND SYSTEM FOR REFINING MODELS FOR A PREDETERMINED CHARACTERISTIC

(71) Applicant: JPMorgan Chase Bank, N.A., New York, NY (US)

(72) Inventors: Shubham SHARMA, Manhattan, NY (US); Freddy LECUE, Mamaroneck, NY (US); Daniele MAGAZZENI, London (GB)

(73) Assignee: JPMorgan Chase Bank, N.A., New York, NY (US)

(21) Appl. No.: 18/098,322

(22) Filed: Jan. 18, 2023

(51) Int. Cl. G06F 30/27

(52) U.S. Cl. CPC G06F 30/27

(57) ABSTRACT

A method for facilitating model refinement via evolutive computation for a predetermined characteristic is disclosed. The method includes capturing a model explanation for a model based on a sampled data set, the model explanation including a listing of model features based on feature scores; identifying feature sets based on the model explanation, the feature sets including a selection of the model features based on the listing; computing, by using raw data, projected data sets for each of the feature sets based on the corresponding selection; generating a data set graph based on the projected data sets, the data set graph representing a relationship between each of the projected data sets; selecting, by using the data set graph, the projected data sets; and validating the selected projected data sets based on a corresponding target characteristic value and a corresponding computed characteristic value.

### BACKGROUND

### 1. Field of the Disclosure

This technology generally relates to methods and systems for model refinement, and more particularly to methods and systems for facilitating refinement of machine learning models via evolutive computation for a predetermined characteristic by exploring graph structure of model explanations.

### 2. Background Information

Many business entities implement predictive systems that rely on machine learning models to facilitate day-to-day operations. Often, the machine learning models must be refined and trained for certain characteristics such as, for example, fairness to achieve desired predictive qualities. Historically, conventional implementations of model refinement techniques have resulted in varying degrees of success with respect to scalability and resource efficiency when it comes to computing machine learning models for predetermined characteristics.

One drawback of using the conventional model refinement techniques is that in many instances, refining the machine learning models for predetermined characteristics requires perturbation of features as well as grouping strategies to identify the best combination of features that remain both accurate and reflective of the characteristics at inference time. As a result, computing machine learning models that are reflective of the predetermined characteristics is a resource intensive and non-scalable process. Additionally, due to the perturbation of features, large investments of time may be required to compute the machine learning models.

Therefore, there is a need for a novel process to structure data and machine learning models using explanation relationships between each of the machine learning models such that the graph structure of the explanation relationships may be explored to identify relevant machine learning models for evaluation and computation.

### SUMMARY

The present disclosure, through one or more of its various aspects, embodiments, and/or specific features or sub-components, provides, inter alia, various systems, servers, devices, methods, media, programs, and platforms for facilitating refinement of machine learning models via evolutive computation for a predetermined characteristic by exploring graph structure of model explanations.

According to an aspect of the present disclosure, a method for facilitating model refinement via evolutive computation for a predetermined characteristic is disclosed. The method is implemented by at least one processor. The method may include capturing a model explanation for at least one model based on a sampled data set, the model explanation may include a listing of a plurality of model features based on at least one feature score; identifying at least one feature set based on the model explanation, the at least one feature set may include a selection of the plurality of model features based on the listing; computing, by using raw data, at least one projected data set for each of the at least one feature set based on the corresponding selection; generating a data set graph based on the at least one projected data set, the data set graph may represent a relationship between each of the at least one projected data set; selecting, by using the data set graph, the at least one projected data set; and validating the selected at least one projected data set based on a corresponding target characteristic value and a corresponding computed characteristic value.

In accordance with an exemplary embodiment, the method may further include determining whether the selected at least one projected data set represents the predetermined characteristic based on a result of the validating, wherein the selected at least one projected data set may represent the predetermined characteristic when the computed characteristic value is higher than the target characteristic value; and wherein the selected at least one projected data set may not represent the predetermined characteristic when the computed characteristic value is lower than the target characteristic value.

In accordance with an exemplary embodiment, when the computed characteristic value is lower than the target characteristic value, the method may further include identifying at least one new feature set based on the model explanation, the at least one new feature set may include a new selection of the plurality of model features based on the listing; computing, by using the raw data, at least one new projected data set for each of the at least one new feature set based on the corresponding new selection; generating a new data set graph based on the at least one new projected data set; selecting, by using the new data set graph, the at least one new projected data set; and validating the selected at least one new projected data set based on the target characteristic value and a new computed characteristic value.

In accordance with an exemplary embodiment, when the computed characteristic value is higher than the target characteristic value, the method may further include outputting the selected at least one projected data set together with a corresponding characteristic compliant explanation for use with the at least one model, wherein predictive results of the at least one model may reflect the predetermined characteristic.

In accordance with an exemplary embodiment, prior to capturing the model explanation, the method may further include receiving, via an application programming interface, at least one input, the at least one input may include the raw data, a data distribution sampling parameter, a model accuracy target value, and the target characteristic value; generating the at least one model by using the raw data, the at least one model may correspond to a predictive model; determining a model accuracy score for each of the at least one model; and determining the computed characteristic value for each of the at least one model.

In accordance with an exemplary embodiment, the method may further include generating, from the raw data, the sampled data set by using the data distribution sampling parameter, wherein the data distribution sampling parameter may include a first selection of random data points from the raw data; wherein the data distribution sampling parameter may include a second selection of data points with a predetermined feature attribute from the raw data; and wherein the data distribution sampling parameter may include a third selection of sequential data points from the raw data.

In accordance with an exemplary embodiment, the model explanation may correspond to a numerical value that represents a contribution of each of the plurality of model features to the at least one model.

In accordance with an exemplary embodiment, the data set graph may be generated based on a predetermined similarity between each of the at least one projected data set, the predetermined similarity may include a numerical amount that relates to a magnitude of feature difference.

In accordance with an exemplary embodiment, the at least one model may include at least one from among a machine learning model, a mathematical model, a process model, and a data model.

According to an aspect of the present disclosure, a computing device configured to implement an execution of a method for facilitating model refinement via evolutive computation for a predetermined characteristic is disclosed. The computing device including a processor; a memory; and a communication interface coupled to each of the processor and the memory, wherein the processor may be configured to capture a model explanation for at least one model based on a sampled data set, the model explanation may include a listing of a plurality of model features based on at least one feature score; identify at least one feature set based on the model explanation, the at least one feature set may include a selection of the plurality of model features based on the listing; compute, by using raw data, at least one projected data set for each of the at least one feature set based on the corresponding selection; generate a data set graph based on the at least one projected data set, the data set graph may represent a relationship between each of the at least one projected data set; select, by using the data set graph, the at least one projected data set; and validate the selected at least one projected data set based on a corresponding target characteristic value and a corresponding computed characteristic value.

In accordance with an exemplary embodiment, the processor may be further configured to determine whether the selected at least one projected data set represents the predetermined characteristic based on a result of the validating, wherein the selected at least one projected data set may represent the predetermined characteristic when the computed characteristic value is higher than the target characteristic value; and wherein the selected at least one projected data set may not represent the predetermined characteristic when the computed characteristic value is lower than the target characteristic value.

In accordance with an exemplary embodiment, when the computed characteristic value is lower than the target characteristic value, the processor may be further configured to identify at least one new feature set based on the model explanation, the at least one new feature set may include a new selection of the plurality of model features based on the listing; compute, by using the raw data, at least one new projected data set for each of the at least one new feature set based on the corresponding new selection; generate a new data set graph based on the at least one new projected data set; select, by using the new data set graph, the at least one new projected data set; and validate the selected at least one new projected data set based on the target characteristic value and a new computed characteristic value.

In accordance with an exemplary embodiment, when the computed characteristic value is higher than the target characteristic value, the processor may be further configured to output the selected at least one projected data set together with a corresponding characteristic compliant explanation for use with the at least one model, wherein predictive results of the at least one model may reflect the predetermined characteristic.

In accordance with an exemplary embodiment, prior to capturing the model explanation, the processor may be further configured to receive, via an application programming interface, at least one input, the at least one input may include the raw data, a data distribution sampling parameter, a model accuracy target value, and the target characteristic value; generate the at least one model by using the raw data, the at least one model may correspond to a predictive model; determine a model accuracy score for each of the at least one model; and determine the computed characteristic value for each of the at least one model.

In accordance with an exemplary embodiment, the processor may be further configured to generate, from the raw data, the sampled data set by using the data distribution sampling parameter, wherein the data distribution sampling parameter may include a first selection of random data points from the raw data; wherein the data distribution sampling parameter may include a second selection of data points with a predetermined feature attribute from the raw data; and wherein the data distribution sampling parameter may include a third selection of sequential data points from the raw data.

In accordance with an exemplary embodiment, the model explanation may correspond to a numerical value that represents a contribution of each of the plurality of model features to the at least one model.

In accordance with an exemplary embodiment, the processor may be further configured to generate the data set graph based on a predetermined similarity between each of the at least one projected data set, the predetermined similarity may include a numerical amount that relates to a magnitude of feature difference.

In accordance with an exemplary embodiment, the at least one model may include at least one from among a machine learning model, a mathematical model, a process model, and a data model.

According to an aspect of the present disclosure, a non-transitory computer readable storage medium storing instructions for facilitating model refinement via evolutive computation for a predetermined characteristic is disclosed. The storage medium including executable code which, when executed by a processor, may cause the processor to capture a model explanation for at least one model based on a sampled data set, the model explanation may include a listing of a plurality of model features based on at least one feature score; identify at least one feature set based on the model explanation, the at least one feature set may include a selection of the plurality of model features based on the listing; compute, by using raw data, at least one projected data set for each of the at least one feature set based on the corresponding selection; generate a data set graph based on the at least one projected data set, the data set graph may represent a relationship between each of the at least one projected data set; select, by using the data set graph, the at least one projected data set; and validate the selected at least one projected data set based on a corresponding target characteristic value and a corresponding computed characteristic value.

In accordance with an exemplary embodiment, when executed by the processor, the executable code may further cause the processor to determine whether the selected at least one projected data set represents the predetermined characteristic based on a result of the validating, wherein the selected at least one projected data set may represent the predetermined characteristic when the computed characteristic value is higher than the target characteristic value; and wherein the selected at least one projected data set may not represent the predetermined characteristic when the computed characteristic value is lower than the target characteristic value.

### BRIEF DESCRIPTION OF THE DRAWINGS

The present disclosure is further described in the detailed description which follows, in reference to the noted plurality of drawings, by way of non-limiting examples of preferred embodiments of the present disclosure, in which like characters represent like elements throughout the several views of the drawings.

FIG. 1 illustrates an exemplary computer system.

FIG. 2 illustrates an exemplary diagram of a network environment.

FIG. 3 shows an exemplary system for implementing a method for facilitating refinement of machine learning models via evolutive computation for a predetermined characteristic by exploring graph structure of model explanations.

FIG. 4 is a flowchart of an exemplary process for implementing a method for facilitating refinement of machine learning models via evolutive computation for a predetermined characteristic by exploring graph structure of model explanations.

### DETAILED DESCRIPTION

Through one or more of its various aspects, embodiments and/or specific features or sub-components of the present disclosure are intended to bring out one or more of the advantages as specifically described above and noted below.

The examples may also be embodied as one or more non-transitory computer readable media having instructions stored thereon for one or more aspects of the present technology as described and illustrated by way of the examples herein. The instructions in some examples include executable code that, when executed by one or more processors, cause the processors to carry out steps necessary to implement the methods of the examples of this technology that are described and illustrated herein.

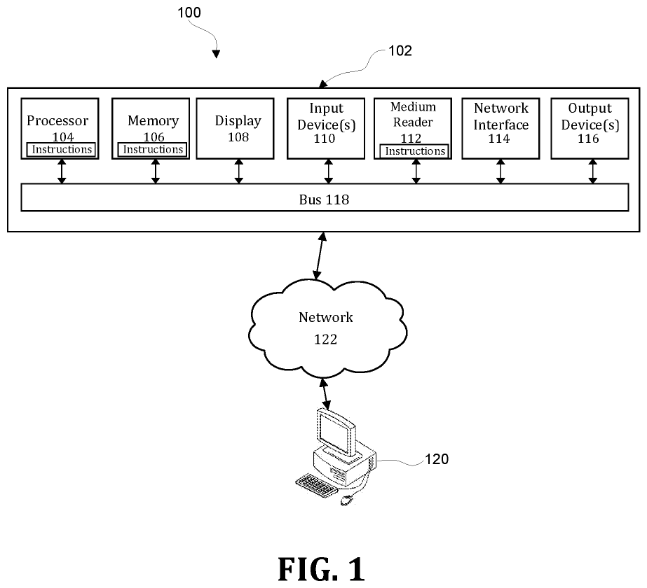

FIG. 1 is an exemplary system for use in accordance with the embodiments described herein. The system 100 is generally shown and may include a computer system 102, which is generally indicated.

The computer system 102 may include a set of instructions that can be executed to cause the computer system 102 to perform any one or more of the methods or computer-based functions disclosed herein, either alone or in combination with the other described devices. The computer system 102 may operate as a standalone device or may be connected to other systems or peripheral devices. For example, the computer system 102 may include, or be included within, any one or more computers, servers, systems, communication networks or cloud environment. Even further, the instructions may be operative in such cloud-based computing environment.

In a networked deployment, the computer system 102 may operate in the capacity of a server or as a client user computer in a server-client user network environment, a client user computer in a cloud computing environment, or as a peer computer system in a peer-to-peer (or distributed) network environment. The computer system 102, or portions thereof, may be implemented as, or incorporated into, various devices, such as a personal computer, a virtual desktop computer, a tablet computer, a set-top box, a personal digital assistant, a mobile device, a palmtop computer, a laptop computer, a desktop computer, a communications device, a wireless smart phone, a personal trusted device, a wearable device, a global positioning satellite (GPS) device, a web appliance, or any other machine capable of executing a set of instructions (sequential or otherwise) that specify actions to be taken by that machine. Further, while a single computer system 102 is illustrated, additional embodiments may include any collection of systems or sub-systems that individually or jointly execute instructions or perform functions. The term “system” shall be taken throughout the present disclosure to include any collection of systems or sub-systems that individually or jointly execute a set, or multiple sets, of instructions to perform one or more computer functions.

As illustrated in FIG. 1, the computer system 102 may include at least one processor 104. The processor 104 is tangible and non-transitory. As used herein, the term “non-transitory” is to be interpreted not as an eternal characteristic of a state, but as a characteristic of a state that will last for a period of time. The term “non-transitory” specifically disavows fleeting characteristics such as characteristics of a particular carrier wave or signal or other forms that exist only transitorily in any place at any time. The processor 104 is an article of manufacture and/or a machine component. The processor 104 is configured to execute software instructions in order to perform functions as described in the various embodiments herein. The processor 104 may be a general-purpose processor or may be part of an application specific integrated circuit (ASIC). The processor 104 may also be a microprocessor, a microcomputer, a processor chip, a controller, a microcontroller, a digital signal processor (DSP), a state machine, or a programmable logic device. The processor 104 may also be a logical circuit, including a programmable gate array (PGA) such as a field programmable gate array (FPGA), or another type of circuit that includes discrete gate and/or transistor logic. The processor 104 may be a central processing unit (CPU), a graphics processing unit (GPU), or both. Additionally, any processor described herein may include multiple processors, parallel processors, or both. Multiple processors may be included in, or coupled to, a single device or multiple devices.

The computer system 102 may also include a computer memory 106. The computer memory 106 may include a static memory, a dynamic memory, or both in communication. Memories described herein are tangible storage mediums that can store data and executable instructions, and are non-transitory during the time instructions are stored therein. Again, as used herein, the term “non-transitory” is to be interpreted not as an eternal characteristic of a state, but as a characteristic of a state that will last for a period of time. The term “non-transitory” specifically disavows fleeting characteristics such as characteristics of a particular carrier wave or signal or other forms that exist only transitorily in any place at any time. The memories are an article of manufacture and/or machine component. Memories described herein are computer-readable mediums from which data and executable instructions can be read by a computer. Memories as described herein may be random access memory (RAM), read only memory (ROM), flash memory, electrically programmable read only memory (EPROM), electrically erasable programmable read-only memory (EEPROM), registers, a hard disk, a cache, a removable disk, tape, compact disc read only memory (CD-ROM), digital versatile disc (DVD), floppy disk, blu-ray disc, or any other form of storage medium known in the art. Memories may be volatile or non-volatile, secure and/or encrypted, unsecure and/or unencrypted. Of course, the computer memory 106 may comprise any combination of memories or a single storage.

The computer system 102 may further include a display 108, such as a liquid crystal display (LCD), an organic light emitting diode (OLED), a flat panel display, a solid-state display, a cathode ray tube (CRT), a plasma display, or any other type of display, examples of which are well known to persons skilled in the art.

The computer system 102 may also include at least one input device 110, such as a keyboard, a touch-sensitive input screen or pad, a speech input, a mouse, a remote-control device having a wireless keypad, a microphone coupled to a speech recognition engine, a camera such as a video camera or still camera, a cursor control device, a global positioning system (GPS) device, an altimeter, a gyroscope, an accelerometer, a proximity sensor, or any combination thereof. Those skilled in the art appreciate that various embodiments of the computer system 102 may include multiple input devices 110. Moreover, those skilled in the art further appreciate that the above-listed, exemplary input devices 110 are not meant to be exhaustive and that the computer system 102 may include any additional, or alternative, input devices 110.

The computer system 102 may also include a medium reader 112 which is configured to read any one or more sets of instructions, e.g., software, from any of the memories described herein. The instructions, when executed by a processor, can be used to perform one or more of the methods and processes as described herein. In a particular embodiment, the instructions may reside completely, or at least partially, within the memory 106, the medium reader 112, and/or the processor 110 during execution by the computer system 102.

Furthermore, the computer system 102 may include any additional devices, components, parts, peripherals, hardware, software, or any combination thereof which are commonly known and understood as being included with or within a computer system, such as, but not limited to, a network interface 114 and an output device 116. The output device 116 may be, but is not limited to, a speaker, an audio out, a video out, a remote-control output, a printer, or any combination thereof.

Each of the components of the computer system 102 may be interconnected and communicate via a bus 118 or other communication link. As shown in FIG. 1, the components may each be interconnected and communicate via an internal bus. However, those skilled in the art appreciate that any of the components may also be connected via an expansion bus. Moreover, the bus 118 may enable communication via any standard or other specification commonly known and understood such as, but not limited to, peripheral component interconnect, peripheral component interconnect express, parallel advanced technology attachment, serial advanced technology attachment, etc.

The computer system 102 may be in communication with one or more additional computer devices 120 via a network 122. The network 122 may be, but is not limited to, a local area network, a wide area network, the Internet, a telephony network, a short-range network, or any other network commonly known and understood in the art. The short-range network may include, for example, Bluetooth, Zigbee, infrared, near field communication, ultraband, or any combination thereof. Those skilled in the art appreciate that additional networks 122 which are known and understood may additionally or alternatively be used and that the exemplary networks 122 are not limiting or exhaustive. Also, while the network 122 is shown in FIG. 1 as a wireless network, those skilled in the art appreciate that the network 122 may also be a wired network.

The additional computer device 120 is shown in FIG. 1 as a personal computer. However, those skilled in the art appreciate that, in alternative embodiments of the present application, the computer device 120 may be a laptop computer, a tablet PC, a personal digital assistant, a mobile device, a palmtop computer, a desktop computer, a communications device, a wireless telephone, a personal trusted device, a web appliance, a server, or any other device that is capable of executing a set of instructions, sequential or otherwise, that specify actions to be taken by that device. Of course, those skilled in the art appreciate that the above-listed devices are merely exemplary devices and that the device 120 may be any additional device or apparatus commonly known and understood in the art without departing from the scope of the present application. For example, the computer device 120 may be the same or similar to the computer system 102. Furthermore, those skilled in the art similarly understand that the device may be any combination of devices and apparatuses.

Of course, those skilled in the art appreciate that the above-listed components of the computer system 102 are merely meant to be exemplary and are not intended to be exhaustive and/or inclusive. Furthermore, the examples of the components listed above are also meant to be exemplary and similarly are not meant to be exhaustive and/or inclusive.

In accordance with various embodiments of the present disclosure, the methods described herein may be implemented using a hardware computer system that executes software programs. Further, in an exemplary, non-limited embodiment, implementations can include distributed processing, component/object distributed processing, and parallel processing. Virtual computer system processing can be constructed to implement one or more of the methods or functionalities as described herein, and a processor described herein may be used to support a virtual processing environment.

As described herein, various embodiments provide optimized methods and systems for facilitating refinement of machine learning models via evolutive computation for a predetermined characteristic by exploring graph structure of model explanations.

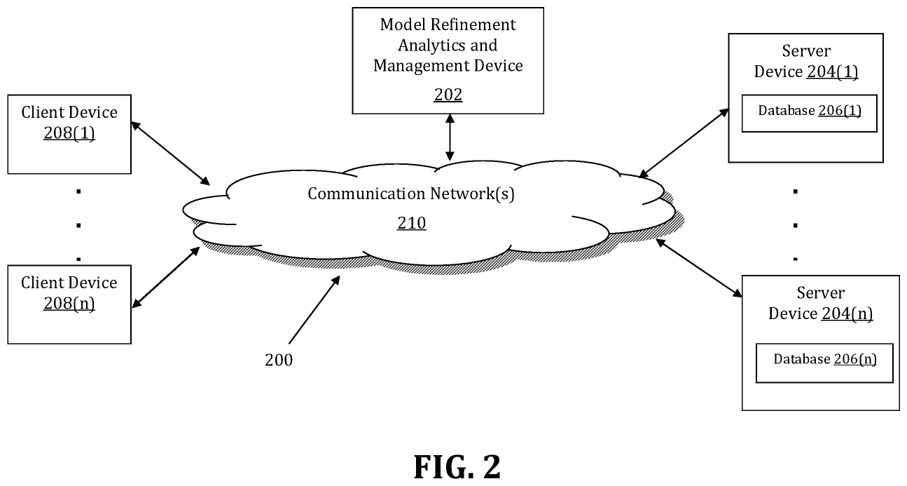

Referring to FIG. 2, a schematic of an exemplary network environment 200 for implementing a method for facilitating refinement of machine learning models via evolutive computation for a predetermined characteristic by exploring graph structure of model explanations is illustrated. In an exemplary embodiment, the method is executable on any networked computer platform, such as, for example, a personal computer (PC).

The method for facilitating refinement of machine learning models via evolutive computation for a predetermined characteristic by exploring graph structure of model explanations may be implemented by a Model Refinement Analytics and Management (MRAM) device 202. The MRAM device 202 may be the same or similar to the computer system 102 as described with respect to FIG. 1. The MRAM device 202 may store one or more applications that can include executable instructions that, when executed by the MRAM device 202, cause the MRAM device 202 to perform actions, such as to transmit, receive, or otherwise process network messages, for example, and to perform other actions described and illustrated below with reference to the figures. The application(s) may be implemented as modules or components of other applications. Further, the application(s) can be implemented as operating system extensions, modules, plugins, or the like.

Even further, the application(s) may be operative in a cloud-based computing environment. The application(s) may be executed within or as virtual machine(s) or virtual server(s) that may be managed in a cloud-based computing environment. Also, the application(s), and even the MRAM device 202 itself, may be located in virtual server(s) running in a cloud-based computing environment rather than being tied to one or more specific physical network computing devices. Also, the application(s) may be running in one or more virtual machines (VMs) executing on the MRAM device 202. Additionally, in one or more embodiments of this technology, virtual machine(s) running on the MRAM device 202 may be managed or supervised by a hypervisor.

In the network environment 200 of FIG. 2, the MRAM device 202 is coupled to a plurality of server devices 204(1)-204(n) that hosts a plurality of databases 206(1)-206(n), and also to a plurality of client devices 208(1)-208(n) via communication network(s) 210. A communication interface of the MRAM device 202, such as the network interface 114 of the computer system 102 of FIG. 1, operatively couples and communicates between the MRAM device 202, the server devices 204(1)-204(n), and/or the client devices 208(1)-208(n), which are all coupled together by the communication network(s) 210, although other types and/or numbers of communication networks or systems with other types and/or numbers of connections and/or configurations to other devices and/or elements may also be used.

The communication network(s) 210 may be the same or similar to the network 122 as described with respect to FIG. 1, although the MRAM device 202, the server devices 204(1)-204(n), and/or the client devices 208(1)-208(n) may be coupled together via other topologies. Additionally, the network environment 200 may include other network devices such as one or more routers and/or switches, for example, which are well known in the art and thus will not be described herein. This technology provides a number of advantages including methods, non-transitory computer readable media, and MRAM devices that efficiently implement a method for facilitating refinement of machine learning models via evolutive computation for a predetermined characteristic by exploring graph structure of model explanations.

By way of example only, the communication network(s) 210 may include local area network(s) (LAN(s)) or wide area network(s) (WAN(s)), and can use TCP/IP over Ethernet and industry-standard protocols, although other types and/or numbers of protocols and/or communication networks may be used. The communication network(s) 210 in this example may employ any suitable interface mechanisms and network communication technologies including, for example, teletraffic in any suitable form (e.g., voice, modem, and the like), Public Switched Telephone Network (PSTNs), Ethernet-based Packet Data Networks (PDNs), combinations thereof, and the like.

The MRAM device 202 may be a standalone device or integrated with one or more other devices or apparatuses, such as one or more of the server devices 204(1)-204(n), for example. In one particular example, the MRAM device 202 may include or be hosted by one of the server devices 204(1)-204(n), and other arrangements are also possible. Moreover, one or more of the devices of the MRAM device 202 may be in a same or a different communication network including one or more public, private, or cloud networks, for example.

The plurality of server devices 204(1)-204(n) may be the same or similar to the computer system 102 or the computer device 120 as described with respect to FIG. 1, including any features or combination of features described with respect thereto. For example, any of the server devices 204(1)-204(n) may include, among other features, one or more processors, a memory, and a communication interface, which are coupled together by a bus or other communication link, although other numbers and/or types of network devices may be used. The server devices 204(1)-204(n) in this example may process requests received from the MRAM device 202 via the communication network(s) 210 according to the HTTP-based and/or JavaScript Object Notation (JSON) protocol, for example, although other protocols may also be used.

The server devices 204(1)-204(n) may be hardware or software or may represent a system with multiple servers in a pool, which may include internal or external networks. The server devices 204(1)-204(n) hosts the databases 206(1)-206(n) that are configured to store data that relates to predetermined characteristics, machine learning models, model explanations, sampled data sets, model features, feature sets, projected data sets, data set graphs, target characteristic values, computed characteristic values, data distribution sampling parameters, and model accuracy target values.

Although the server devices 204(1)-204(n) are illustrated as single devices, one or more actions of each of the server devices 204(1)-204(n) may be distributed across one or more distinct network computing devices that together comprise one or more of the server devices 204(1)-204(n). Moreover, the server devices 204(1)-204(n) are not limited to a particular configuration. Thus, the server devices 204(1)-204(n) may contain a plurality of network computing devices that operate using a controller/agent approach, whereby one of the network computing devices of the server devices 204(1)-204(n) operates to manage and/or otherwise coordinate operations of the other network computing devices.

The server devices 204(1)-204(n) may operate as a plurality of network computing devices within a cluster architecture, a peer-to peer architecture, virtual machines, or within a cloud architecture, for example. Thus, the technology disclosed herein is not to be construed as being limited to a single environment and other configurations and architectures are also envisaged.

The plurality of client devices 208(1)-208(n) may also be the same or similar to the computer system 102 or the computer device 120 as described with respect to FIG. 1, including any features or combination of features described with respect thereto. For example, the client devices 208(1)-208(n) in this example may include any type of computing device that can interact with the MRAM device 202 via communication network(s) 210. Accordingly, the client devices 208(1)-208(n) may be mobile computing devices, desktop computing devices, laptop computing devices, tablet computing devices, virtual machines (including cloud-based computers), or the like, that host chat, e-mail, or voice-to-text applications, for example. In an exemplary embodiment, at least one client device 208 is a wireless mobile communication device, i.e., a smart phone.

The client devices 208(1)-208(n) may run interface applications, such as standard web browsers or standalone client applications, which may provide an interface to communicate with the MRAM device 202 via the communication network(s) 210 in order to communicate user requests and information. The client devices 208(1)-208(n) may further include, among other features, a display device, such as a display screen or touchscreen, and/or an input device, such as a keyboard, for example.

Although the exemplary network environment 200 with the MRAM device 202, the server devices 204(1)-204(n), the client devices 208(1)-208(n), and the communication network(s) 210 are described and illustrated herein, other types and/or numbers of systems, devices, components, and/or elements in other topologies may be used. It is to be understood that the systems of the examples described herein are for exemplary purposes, as many variations of the specific hardware and software used to implement the examples are possible, as will be appreciated by those skilled in the relevant art(s).

One or more of the devices depicted in the network environment 200, such as the MRAM device 202, the server devices 204(1)-204(n), or the client devices 208(1)-208(n), for example, may be configured to operate as virtual instances on the same physical machine. In other words, one or more of the MRAM device 202, the server devices 204(1)-204(n), or the client devices 208(1)-208(n) may operate on the same physical device rather than as separate devices communicating through communication network(s) 210. Additionally, there may be more or fewer MRAM devices 202, server devices 204(1)-204(n), or client devices 208(1)-208(n) than illustrated in FIG. 2.

In addition, two or more computing systems or devices may be substituted for any one of the systems or devices in any example. Accordingly, principles and advantages of distributed processing, such as redundancy and replication, also may be implemented, as desired, to increase the robustness and performance of the devices and systems of the examples. The examples may also be implemented on computer system(s) that extend across any suitable network using any suitable interface mechanisms and traffic technologies, including by way of example only teletraffic in any suitable form (e.g., voice and modem), wireless traffic networks, cellular traffic networks, Packet Data Networks (PDNs), the Internet, intranets, and combinations thereof.

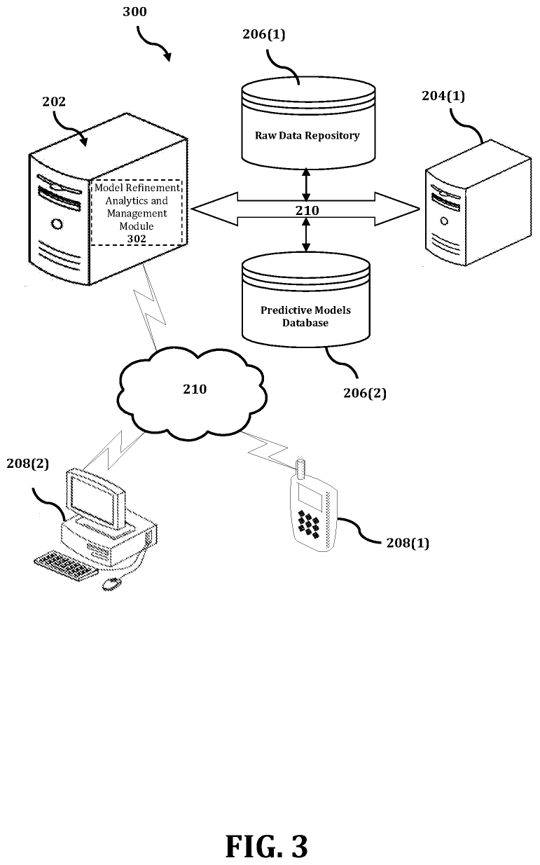

The MRAM device 202 is described and shown in FIG. 3 as including a model refinement analytics and management module 302, although it may include other rules, policies, modules, databases, or applications, for example. As will be described below, the model refinement analytics and management module 302 is configured to implement a method for facilitating refinement of machine learning models via evolutive computation for a predetermined characteristic by exploring graph structure of model explanations.

An exemplary process 300 for implementing a mechanism for facilitating refinement of machine learning models via evolutive computation for a predetermined characteristic by exploring graph structure of model explanations by utilizing the network environment of FIG. 2 is shown as being executed in FIG. 3. Specifically, a first client device 208(1) and a second client device 208(2) are illustrated as being in communication with MRAM device 202. In this regard, the first client device 208(1) and the second client device 208(2) may be “clients” of the MRAM device 202 and are described herein as such. Nevertheless, it is to be known and understood that the first client device 208(1) and/or the second client device 208(2) need not necessarily be “clients” of the MRAM device 202, or any entity described in association therewith herein. Any additional or alternative relationship may exist between either or both of the first client device 208(1) and the second client device 208(2) and the MRAM device 202, or no relationship may exist.

Further, MRAM device 202 is illustrated as being able to access a raw data repository 206(1) and a predictive models database 206(2). The model refinement analytics and management module 302 may be configured to access these databases for implementing a method for facilitating refinement of machine learning models via evolutive computation for a predetermined characteristic by exploring graph structure of model explanations.

The first client device 208(1) may be, for example, a smart phone. Of course, the first client device 208(1) may be any additional device described herein. The second client device 208(2) may be, for example, a personal computer (PC). Of course, the second client device 208(2) may also be any additional device described herein.

The process may be executed via the communication network(s) 210, which may comprise plural networks as described above. For example, in an exemplary embodiment, either or both of the first client device 208(1) and the second client device 208(2) may communicate with the MRAM device 202 via broadband or cellular communication. Of course, these embodiments are merely exemplary and are not limiting or exhaustive.

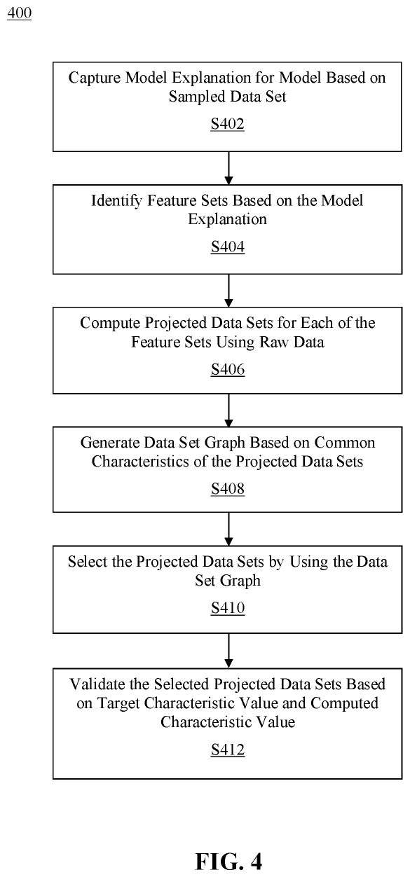

Upon being started, the model refinement analytics and management module 302 executes a process for facilitating refinement of machine learning models via evolutive computation for a predetermined characteristic by exploring graph structure of model explanations. An exemplary process for facilitating refinement of machine learning models via evolutive computation for a predetermined characteristic by exploring graph structure of model explanations is generally indicated at flowchart 400 in FIG. 4.

In the process 400 of FIG. 4, at step S402, model explanations for a plurality of models may be captured based on a sampled data set. The model explanation may include a listing of model features based on feature scores. In an exemplary embodiment, the model explanations may be computed for each of the models with respect to input background data such as, for example, the sampled data set obtained from input raw data based on a data distribution sampling strategy. The model explanations may be captured as a ranked list of model features and feature scores. For example, the model explanations may be captured for a given model as a list of model features that have been ranked based on corresponding feature scores.

In another exemplary embodiment, the feature scores in the model explanations may correspond to a numerical value that represents a contribution of each model feature to the corresponding model. For example, the model explanations may be captured for a model “M_R” as a set of explanations and background data “SR1” such that:

$$XAI ( M\_R , SR 1 ) =$$

$$\#1 - A = + 40$$

$$\#2 - B = + 3$$

$$\#3 - C = - 19$$

$$\#4 - D = - 21.$$

In another exemplary embodiment, the feature scores in the model explanations may be captured by using various approaches falling under feature attribution/importance methods such as, for example, a SHAPELY Additive Explanations (SHAP) approach. The SHAP approach may break down a prediction to show the impact of each feature. For example, the SHAP approach may break down a prediction derived from model “M_R” and the background data “SR1” to show the impact of model features “A”, “B”, “C”, and “D”, as provided above. In this example, the higher the feature score for a model feature, the greater the contribution of that model feature to the predictive outcome.

In another exemplary embodiment, the model may include at least one from among a machine learning model, a mathematical model, a process model, and a data model. The model may also include stochastic models such as, for example, a Markov model that is used to model randomly changing systems. In stochastic models, the future states of a system may be assumed to depend only on the current state of the system.

In another exemplary embodiment, machine learning and pattern recognition may include supervised learning algorithms such as, for example, k-medoids analysis, regression analysis, decision tree analysis, random forest analysis, k-nearest neighbors analysis, logistic regression analysis, etc. In another exemplary embodiment, machine learning analytical techniques may include unsupervised learning algorithms such as, for example, Apriori analysis, K-means clustering analysis, etc. In another exemplary embodiment, machine learning analytical techniques may include reinforcement learning algorithms such as, for example, Markov Decision Process analysis, etc.

In another exemplary embodiment, the model may be based on a machine learning algorithm. The machine learning algorithm may include at least one from among a process and a set of rules to be followed by a computer in calculations and other problem-solving operations such as, for example, a linear regression algorithm, a logistic regression algorithm, a decision tree algorithm, and/or a Naive Bayes algorithm.

In another exemplary embodiment, the model may include training models such as, for example, a machine learning model which is generated to be further trained on additional data. Once the training model has been sufficiently trained, the training model may be deployed onto various connected systems to be utilized. In another exemplary embodiment, the training model may be sufficiently trained when model assessment methods such as, for example, a holdout method, a K-fold-cross-validation method, and a bootstrap method determine that at least one of the training model's least squares error rate, true positive rate, true negative rate, false positive rate, and false negative rates are within predetermined ranges.

In another exemplary embodiment, the training model may be operable, i.e., actively utilized by an organization, while continuing to be trained using new data. In another exemplary embodiment, the models may be generated using at least one from among an artificial neural network technique, a decision tree technique, a support vector machines technique, a Bayesian network technique, and a genetic algorithms technique.

In another exemplary embodiment, consistent with present disclosures, the sampled data set may result from a sampling of input raw data according to a sampling strategy such as, for example, a data distribution sampling parameter. The sampled data set may be used in computing the model explanation to reduce computational requirements. For instance, the sampled data set may be representative of the raw input data while also including fewer data points. As such, fewer computational resources may be required to capture the model explanations due to the fewer data points.

In another exemplary embodiment, prior to capturing the model explanations, inputs may be received via an application programming interface (API). The inputs may include the raw data, the data distribution sampling parameter, a model accuracy target value, and a target characteristic value. The model accuracy target value may be manifested by statistical metrics for measuring quality of predictions such as, for example, mean squared error. The target characteristic value may be manifested by statistical metrics for measuring a characteristic such as, for example, fairness of a group of individuals such as, for example, equal opportunities and equalized odds.

Then, models may be generated by using the raw data consistent with present disclosures. The models may correspond to a predictive model. A model accuracy score for each of the generated models may also be determined. The model accuracy score may be manifested by statistical metrics for measuring quality of predictions such as, for example, mean squared error. Likewise, a computed characteristic value for each of the generated models may be determined at this step. The computed characteristic value may be manifested by statistical metrics for measuring a characteristic such as, for example, fairness of a group of individuals such as, for example, equal opportunities and equalized odds.

In another exemplary embodiment, consistent with present disclosures, the sampled data set may be generated from the raw data by using the received data distribution sampling parameter. The received data distribution sampling parameter may be predetermined to ensure that the resulting sampled data set accurately represent the raw data. For instance, the data distribution sampling parameter may include a first selection of random data points from the raw data. Further, the data distribution sampling parameter may include a second selection of data points with a predetermined feature attribute from the raw data. Likewise, the data distribution sampling parameter may include a third selection of sequential data points from the raw data.

At step S404, feature sets may be identified based on the model explanation. The feature sets may include a selection of model features based on the listing of the model features. In an exemplary embodiment, the feature sets may be generated based on a result of the model explanation computation and corresponding ranking. For example, the feature sets may include the top three features of a given model as ranked in the model explanation.

In another exemplary embodiment, the feature sets may be identified according to an exemplary process such that:
For each pair of explanation, background data, and fitness score
   Select top “k” features from explanation and background data
   Store selection in FEATURE_LIST
   Add FEATURES_LIST to FEATURES_SET
Return FEATURES_SET.

In the above exemplary process, the fitness score may be a score that evaluates the characteristic value of the model by using the selected features.

In another exemplary embodiment, each of the feature sets may be combined with a corresponding sampling strategy and a corresponding fitness score. Consistent with present disclosures, each of the feature sets may correspond to a generated machine learning model.

At step S406, projected data sets may be computed for each of the feature sets based on the corresponding selection of model features. The projected data sets may be computed by using the raw data. In an exemplary embodiment, the projected data sets may be generated from the initial data set represented by only a subgroup of features from step S404. For example, the projected data sets may correspond to outcomes achieved by using the feature sets (i.e., the top three features of a given model) and the raw data.

In another exemplary embodiment, the feature sets may be computed according to an exemplary process such that:
For each FEATURE_LIST in FEATURES_SET
   FEATURE_DATA_LIST=data associated with FEATURE_LIST, background data, and fitness score
   Add FEATURED_DATA_LIST to FEATURED_DATA_SET
Return FEATURED_DATA_SET.

Wherein the projected data sets may correspond to a projection of the raw data on the feature sets. Consistent with present disclosures, the fitness score in the above exemplary process may be a score that evaluates the characteristic value of the model by using the selected features.

At step S408, a data set graph may be generated based on the projected data sets. The data set graph may represent a relationship between each of the projected data sets. In an exemplary embodiment, the data set graph may be generated based on a predetermined similarity between each of the projected data sets. The predetermined similarity may include a numerical amount that relates to a magnitude of feature differences. In another exemplary embodiment, the data set graph may be generated based on characteristics that are in common between each of the projected data sets. The common characteristics may relate to features and/or qualities that are shared between the projected data sets. Consistent with present disclosures, the common characteristics may include the predetermined characteristic.

Then, at step S410, projected data sets may be selected by using the data set graph. Consistent with present disclosures, the projected data sets that are most similar according to the data set graph may be selected. Step S408 and step S410 are aimed at selecting some of the input data sets to re-compute a model and run model evaluation.

In another exemplary embodiment, step S408 and step S410 may be implemented according to an exemplary process such that:
For each FEATURED_DATA_LIST1 and FEATURED_DATA_LIST2 in FEATURED_DATA_SET
   If exist FEATURED_DATA_LIST1 and FEATURED_DATA_LIST2 in FEATURED_DATA_SET such that:
      FEATURED_DATA_LIST1 and FEATURED_DATA_LIST2 are only different from 1 feature, connect FEATURED_DATA_LIST1 and FEATURED_DATA_LIST2 in a data set graph
Select the data sets which are the most connected in the data set graph.

At step S412, the selected, projected data sets may be validated based on the corresponding target characteristic value and the correspond computed characteristic value. In an exemplary embodiment, the validation of the selected, projected data sets may be aimed at quantifying the predetermined characteristic of the model based on criteria that are set as input. The selected, projected data sets may be tested to determine whether a resulting model satisfies predetermined characteristic requirements such as, for example, fairness. When the resulting model satisfies the predetermined characteristic requirements, the resulting model may reflect the desired characteristic.

In another exemplary embodiment, a determination may be made as to whether the selected, projected data sets represent the predetermined characteristic. The determination may be made based on a result of the validating such that the selected, projected data sets represent the predetermined characteristic when the computed characteristic value is higher than the target characteristic value. Conversely, the selected, projected data sets do not represent the predetermined characteristic when the computed characteristic value is lower than the target characteristic value.

In another exemplary embodiment, the selected, projected data sets may be validated according to an exemplary process such that:
If computed fairness is higher than target fairness then done; model is fair with respect to data
Else, move to step S404, or stop after a period of time has elapsed.

When the model is not able to satisfy the fairness constraint, the model explanation may not be trustworthy to identify a fair model.

In another exemplary embodiment, when the computed characteristic value is lower than the target characteristic value, new feature sets may be identified based on the model explanation. The new feature sets may include a new selection of model features based on the listing of model features. New projected data sets may be computed for each of the new feature sets based on the correspond new selection of model features. The new projected data sets may be computed by using the raw data. A new data set graph may also be generated based on the new projected data sets. Then, the new projected data sets may be selected by using the new data set graph. Consistent with present disclosures, the selected new projected data sets may be validated based on the target characteristic value and a new computed characteristic value. As will be appreciated by a person of ordinary skill in the art, this process may be repeated until a criterion is satisfied such as, for example, the new computed characteristic value is higher than the target characteristic value.

In another exemplary embodiment, when the computed characteristic value is higher than the target characteristic value, the selected, projected data sets may be outputted together with a corresponding characteristic compliant explanation for use with the model. The selected, projected data sets that are outputted may be used with the model such that predictive results of the model reflect the predetermined characteristic. For example, the selected, projected data sets that are outputted may be usable with the model for fair predictions.

In another exemplary embodiment, the selected, projected data sets may be outputted together with a corresponding characteristic compliant explanation via a graphical user interface. The graphical user interface may enable interactions between a user and the claimed invention. For example, a notification may be provided to the user via the graphical user interface to alert the user of a completed selection process. In another exemplary embodiment, the graphical user interface may graphically and/or textually present information to the user together with the selected, projected data sets and the corresponding characteristic compliant explanation. The information may correspond to a result of steps S400 to S412 as presented above.

In another exemplary embodiment, the graphical user interface may alert the user of any detected errors such as, for example, when the explanation is not trustworthy to identify a fair model. The graphical user interface may also provide recommendations for the user to adjust various parameters to improve adherence to the predetermined characteristic. For example, the graphical user interface may indicate that adjustment of parameters A and B may improve model fairness.

Accordingly, with this technology, an optimized process for facilitating refinement of machine learning models via evolutive computation for a predetermined characteristic by exploring graph structure of model explanations is disclosed.

Although the invention has been described with reference to several exemplary embodiments, it is understood that the words that have been used are words of description and illustration, rather than words of limitation. Changes may be made within the purview of the appended claims, as presently stated and as amended, without departing from the scope and spirit of the present disclosure in its aspects. Although the invention has been described with reference to particular means, materials and embodiments, the invention is not intended to be limited to the particulars disclosed; rather the invention extends to all functionally equivalent structures, methods, and uses such as are within the scope of the appended claims.

For example, while the computer-readable medium may be described as a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the embodiments disclosed herein.

The computer-readable medium may comprise a non-transitory computer-readable medium or media and/or comprise a transitory computer-readable medium or media. In a particular non-limiting, exemplary embodiment, the computer-readable medium can include a solid-state memory such as a memory card or other package that houses one or more non-volatile read-only memories. Further, the computer-readable medium can be a random-access memory or other volatile re-writable memory. Additionally, the computer-readable medium can include a magneto-optical or optical medium, such as a disk or tapes or other storage device to capture carrier wave signals such as a signal communicated over a transmission medium. Accordingly, the disclosure is considered to include any computer-readable medium or other equivalents and successor media, in which data or instructions may be stored.

Although the present application describes specific embodiments which may be implemented as computer programs or code segments in computer-readable media, it is to be understood that dedicated hardware implementations, such as application specific integrated circuits, programmable logic arrays and other hardware devices, can be constructed to implement one or more of the embodiments described herein. Applications that may include the various embodiments set forth herein may broadly include a variety of electronic and computer systems. Accordingly, the present application may encompass software, firmware, and hardware implementations, or combinations thereof. Nothing in the present application should be interpreted as being implemented or implementable solely with software and not hardware.

Although the present specification describes components and functions that may be implemented in particular embodiments with reference to particular standards and protocols, the disclosure is not limited to such standards and protocols. Such standards are periodically superseded by faster or more efficient equivalents having essentially the same functions. Accordingly, replacement standards and protocols having the same or similar functions are considered equivalents thereof.

The illustrations of the embodiments described herein are intended to provide a general understanding of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

The Abstract of the Disclosure is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A method for facilitating model refinement via evolutive computation for a predetermined characteristic, the method being implemented by at least one processor, the method comprising:
capturing, by the at least one processor, a model explanation for at least one model based on a sampled data set, the model explanation including a listing of a plurality of model features based on at least one feature score;
identifying, by the at least one processor, at least one feature set based on the model explanation, the at least one feature set including a selection of the plurality of model features based on the listing;
computing, by the at least one processor using raw data, at least one projected data set for each of the at least one feature set based on the corresponding selection;
generating, by the at least one processor, a data set graph based on the at least one projected data set, the data set graph representing a relationship between each of the at least one projected data set;
selecting, by the at least one processor using the data set graph, the at least one projected data set; and
validating, by the at least one processor, the selected at least one projected data set based on a corresponding target characteristic value and a corresponding computed characteristic value.

2. The method of claim 1, further comprising:
determining, by the at least one processor, whether the selected at least one projected data set represents the predetermined characteristic based on a result of the validating,
wherein the selected at least one projected data set represents the predetermined characteristic when the computed characteristic value is higher than the target characteristic value; and
wherein the selected at least one projected data set does not represent the predetermined characteristic when the computed characteristic value is lower than the target characteristic value.

3. The method of claim 2, wherein, when the computed characteristic value is lower than the target characteristic value, the method further comprises:
identifying, by the at least one processor, at least one new feature set based on the model explanation, the at least one new feature set including a new selection of the plurality of model features based on the listing;
computing, by the at least one processor using the raw data, at least one new projected data set for each of the at least one new feature set based on the corresponding new selection;
generating, by the at least one processor, a new data set graph based on the at least one new projected data set;
selecting, by the at least one processor using the new data set graph, the at least one new projected data set; and
validating, by the at least one processor, the selected at least one new projected data set based on the target characteristic value and a new computed characteristic value.

4. The method of claim 2, wherein, when the computed characteristic value is higher than the target characteristic value, the method further comprises:
outputting, by the at least one processor, the selected at least one projected data set together with a corresponding characteristic compliant explanation for use with the at least one model,
wherein predictive results of the at least one model reflect the predetermined characteristic.

5. The method of claim 1, wherein, prior to capturing the model explanation, the method further comprises:
receiving, by the at least one processor via an application programming interface, at least one input, the at least one input including the raw data, a data distribution sampling parameter, a model accuracy target value, and the target characteristic value;
generating, by the at least one processor, the at least one model by using the raw data, the at least one model corresponding to a predictive model;
determining, by the at least one processor, a model accuracy score for each of the at least one model; and
determining, by the at least one processor, the computed characteristic value for each of the at least one model.

6. The method of claim 5, further comprising:
generating, by the at least one processor from the raw data, the sampled data set by using the data distribution sampling parameter,
wherein the data distribution sampling parameter includes a first selection of random data points from the raw data;
wherein the data distribution sampling parameter includes a second selection of data points with a predetermined feature attribute from the raw data; and
wherein the data distribution sampling parameter includes a third selection of sequential data points from the raw data.

7. The method of claim 1, wherein the model explanation corresponds to a numerical value that represents a contribution of each of the plurality of model features to the at least one model.

8. The method of claim 1, wherein the data set graph is generated based on a predetermined similarity between each of the at least one projected data set, the predetermined similarity including a numerical amount that relates to a magnitude of feature difference.

9. The method of claim 1, wherein the at least one model includes at least one from among a machine learning model, a mathematical model, a process model, and a data model.

10. A computing device configured to implement an execution of a method for facilitating model refinement via evolutive computation for a predetermined characteristic, the computing device comprising:
a processor;
a memory; and
a communication interface coupled to each of the processor and the memory,
wherein the processor is configured to:
capture a model explanation for at least one model based on a sampled data set, the model explanation including a listing of a plurality of model features based on at least one feature score;
identify at least one feature set based on the model explanation, the at least one feature set including a selection of the plurality of model features based on the listing;
compute, by using raw data, at least one projected data set for each of the at least one feature set based on the corresponding selection;
generate a data set graph based on the at least one projected data set, the data set graph representing a relationship between each of the at least one projected data set;
select, by using the data set graph, the at least one projected data set, and
validate the selected at least one projected data set based on a corresponding target characteristic value and a corresponding computed characteristic value.

11. The computing device of claim 10, wherein the processor is further configured to:
determine whether the selected at least one projected data set represents the predetermined characteristic based on a result of the validating,
wherein the selected at least one projected data set represents the predetermined characteristic when the computed characteristic value is higher than the target characteristic value; and
wherein the selected at least one projected data set does not represent the predetermined characteristic when the computed characteristic value is lower than the target characteristic value.

12. The computing device of claim 11, wherein, when the computed characteristic value is lower than the target characteristic value, the processor is further configured to:
identify at least one new feature set based on the model explanation, the at least one new feature set including a new selection of the plurality of model features based on the listing;
compute, by using the raw data, at least one new projected data set for each of the at least one new feature set based on the corresponding new selection;
generate a new data set graph based on the at least one new projected data set;
select, by using the new data set graph, the at least one new projected data set; and
validate the selected at least one new projected data set based on the target characteristic value and a new computed characteristic value.

13. The computing device of claim 11, wherein, when the computed characteristic value is higher than the target characteristic value, the processor is further configured to:
output the selected at least one projected data set together with a corresponding characteristic compliant explanation for use with the at least one model,
wherein predictive results of the at least one model reflect the predetermined characteristic.

14. The computing device of claim 10, wherein, prior to capturing the model explanation, the processor is further configured to:
receive, via an application programming interface, at least one input, the at least one input including the raw data, a data distribution sampling parameter, a model accuracy target value, and the target characteristic value;
generate the at least one model by using the raw data, the at least one model corresponding to a predictive model;
determine a model accuracy score for each of the at least one model; and
determine the computed characteristic value for each of the at least one model.

15. The computing device of claim 14, wherein the processor is further configured to:
generate, from the raw data, the sampled data set by using the data distribution sampling parameter,
wherein the data distribution sampling parameter includes a first selection of random data points from the raw data;
wherein the data distribution sampling parameter includes a second selection of data points with a predetermined feature attribute from the raw data; and
wherein the data distribution sampling parameter includes a third selection of sequential data points from the raw data.

16. The computing device of claim 10, wherein the model explanation corresponds to a numerical value that represents a contribution of each of the plurality of model features to the at least one model.

17. The computing device of claim 10, wherein the processor is further configured to generate the data set graph based on a predetermined similarity between each of the at least one projected data set, the predetermined similarity including a numerical amount that relates to a magnitude of feature difference.

18. The computing device of claim 10, wherein the at least one model includes at least one from among a machine learning model, a mathematical model, a process model, and a data model.

19. A non-transitory computer readable storage medium storing instructions for facilitating model refinement via evolutive computation for a predetermined characteristic, the storage medium comprising executable code which, when executed by a processor, causes the processor to:
capture a model explanation for at least one model based on a sampled data set, the model explanation including a listing of a plurality of model features based on at least one feature score;
identify at least one feature set based on the model explanation, the at least one feature set including a selection of the plurality of model features based on the listing;
compute, by using raw data, at least one projected data set for each of the at least one feature set based on the corresponding selection;
generate a data set graph based on the at least one projected data set, the data set graph representing a relationship between each of the at least one projected data set;
select, by using the data set graph, the at least one projected data set; and
validate the selected at least one projected data set based on a corresponding target characteristic value and a corresponding computed characteristic value.

20. The storage medium of claim 19, wherein, when executed by the processor, the executable code further causes the processor to:
determine whether the selected at least one projected data set represents the predetermined characteristic based on a result of the validating,
wherein the selected at least one projected data set represents the predetermined characteristic when the computed characteristic value is higher than the target characteristic value; and
wherein the selected at least one projected data set does not represent the predetermined characteristic when the computed characteristic value is lower than the target characteristic value.
